(19) United States
(12) Patent Application Publication
(10) Pub. No.: US 2025/0344423 A1
(43) Pub. Date: Nov. 6, 2025

(54) TREATMENT FOR TUNING THRESHOLD VOLTAGES OF TRANSISTORS

(71) Applicant: Taiwan Semiconductor Manufacturing Co., Ltd., Hsinchu (TW)

(72) Inventors: Chun-Hsiu Chiang, Taipei City (TW); Pei Ying Lai, Hsinchu (TW); Cheng-Hao Hou, Hsinchu (TW); Chi On Chui, Hsinchu (TW); Shan-Mei Liao, Hsinchu (TW); Hung-Chi Wu, Taipei City (TW)

(21) Appl. No.: 19/265,512

(22) Filed: Jul. 10, 2025

Related U.S. Application Data
(63) Continuation of application No. 18/420,550, filed on Jan. 23, 2024.
(60) Provisional application No. 63/591,909, filed on Oct. 20, 2023.

(51) Int. Cl. H10D 30/01; H10D 30/60; H10D 30/62; H10D 64/01

(52) U.S. Cl. CPC H10D 30/0227; H10D 30/024; H10D 30/601; H10D 30/6211; H10D 64/017

(57) ABSTRACT

A method forming a source/drain region based on a first portion of a semiconductor region, forming a high-k dielectric layer based on a second portion of the semiconductor region, forming a dipole film on the high-k dielectric layer, performing a treatment process on the dipole film using a process gas comprising nitrogen and hydrogen, performing a drive-in process to drive a dipole dopant in the dipole film into the high-k dielectric layer, and depositing a work-function layer on the high-k dielectric layer.

### PRIORITY CLAIM AND CROSS-REFERENCE

This application is a continuation of U.S. patent application Ser. No. 18/420,550, filed on Jan. 23, 2024, which application claims the benefit of the following provisionally filed U.S. Patent application: Application No. 63/591,909, filed on Oct. 20, 2023, and entitled “Volume-less p-Vt Dipole Tuning Gap,” which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B, 9A, 9B, 10A, 10B, 10C, 11A, 11B, 12A, 12B, 13A, 13B, 14-24, 25A, 25B, 26A, 26B, 27A, 27B, 28A, and 28B illustrate the intermediate stages in the formation of Gate-All-Around (GAA) transistors in accordance with some embodiments.

FIG. 29 illustrates a process flow for forming multi-Vt devices in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A method of tuning the threshold voltages (Vts) of transistors is provided. In accordance with some embodiments of the present disclosure, a dipole film is deposited, and may be trimmed back to reduce its thickness. A treatment process is performed using a process gas comprising the mixture of nitrogen (N₂) and hydrogen (H₂). The treatment may break the bonds of dipole atoms from their compounds, and may reduce the adverse effect caused by thermal processes, so that the dipole drive-in process is more effective. It is appreciated that although Gate-All-Around (GAA) transistors are used as an example, the concept of the present disclosure may be applied to other types of transistors such as planar transistors, Fin Field-Effect Transistors (FinFETs), Complementary Field-Effect Transistors (CFETs), and the like.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

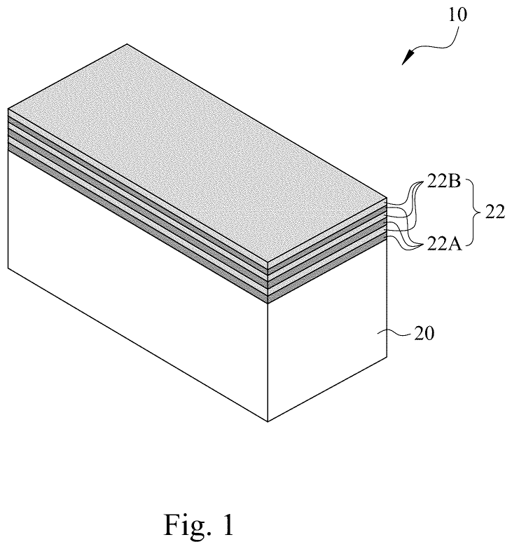

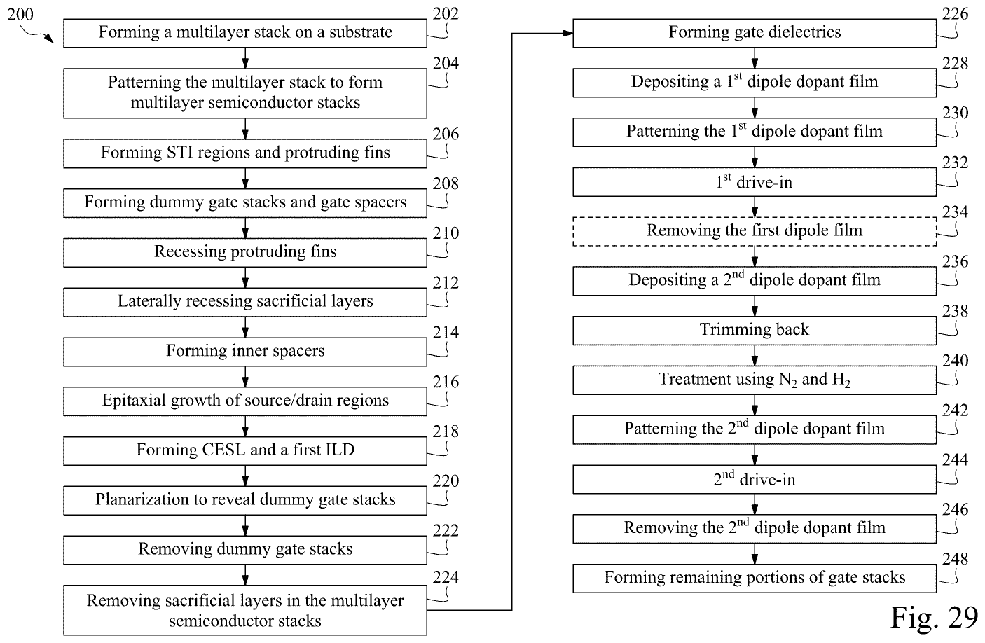

FIGS. 1-4, 5A, 5B, 6A, 6B, 7A, 7B, 8A, 8B, 9A, 9B, 10A, 10B, 10C, 11A, 11B, 12A, 12B, 13A, 13B, 14-24, 25A, 25B, 26A, 26B, 27A, 27B, 28A, and 28B illustrate the intermediate stages in the formation of GAA transistors in accordance with some embodiments. The respective processes are shown in the process flow 200 as shown in FIG. 29.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 shown in FIG. 29. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the second layer 22B may be formed to a second thickness in the range between about 10 Å and about 500 Å, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there are some pad oxide layer(s) and hard mask layer(s) (not shown) formed over multilayer stack 22. These layers are patterned, and are used for the subsequent patterning of multilayer stack 22.

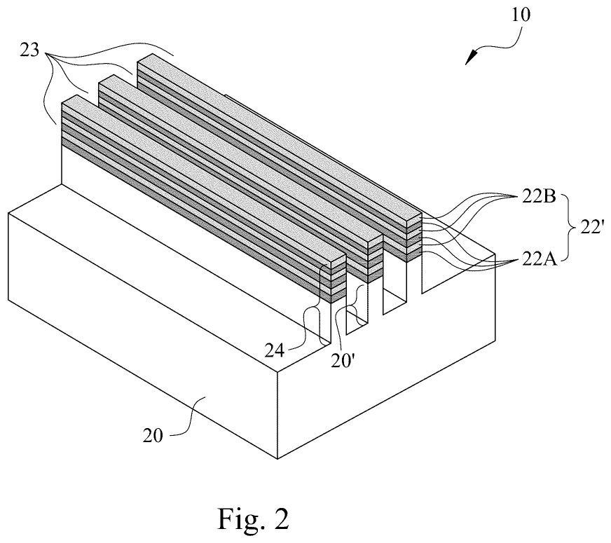

Referring to FIG. 2, multilayer stack 22 and a portion of the underlying substrate 20 are patterned in an etching process(es), so that trenches 23 are formed. The respective process is illustrated as process 204 in the process flow 200 shown in FIG. 29. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

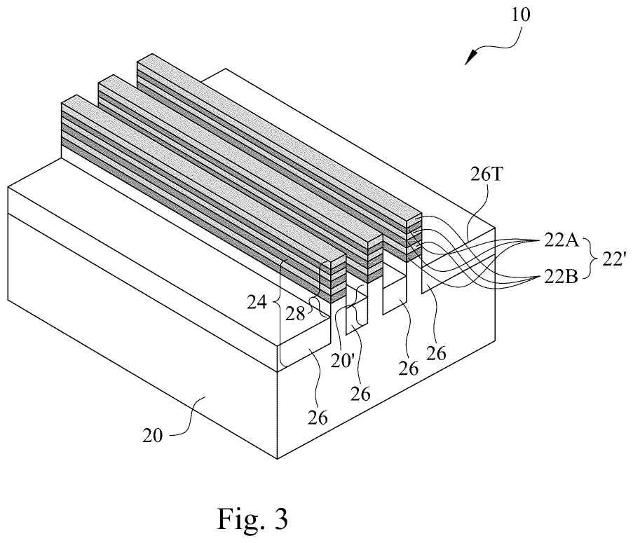

FIG. 3 illustrates the formation of isolation regions 26, which are also referred to as Shallow Trench Isolation (STI) regions throughout the description. The respective process is illustrated as process 206 in the process flow 200 shown in FIG. 29. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

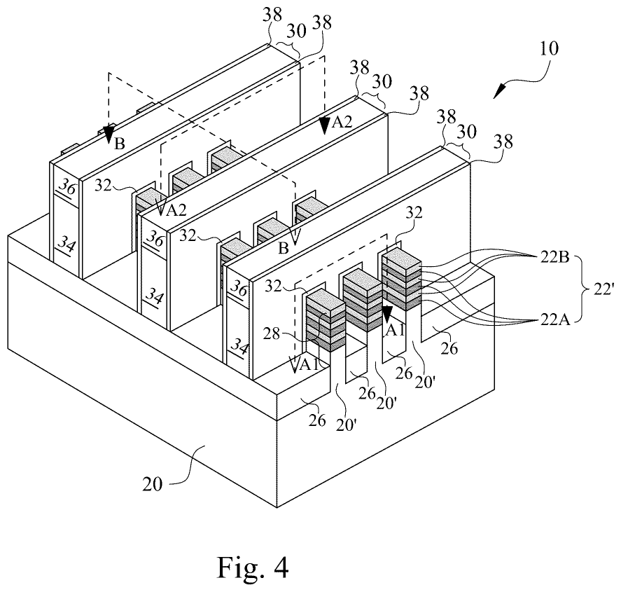

Referring to FIG. 4, dummy gate stacks 30 and gate spacers 38 are formed on the top surfaces and the sidewalls of (protruding) fins 28. The respective process is illustrated as process 208 in the process flow 200 shown in FIG. 29. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

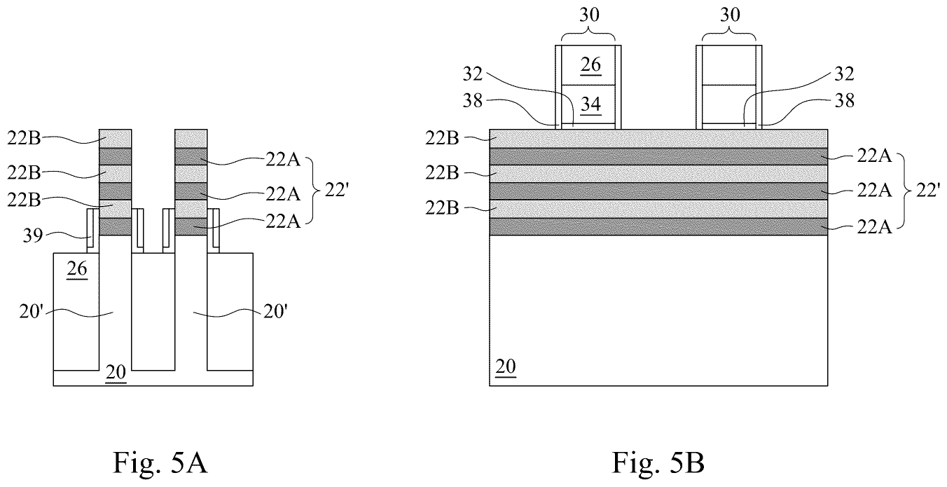

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by gate stacks 30 and gate spacers 38, and is perpendicular to the gate-length direction. Fin spacers 38, which are on the sidewalls of protruding fins 28, are also illustrated. FIG. 5B illustrates the reference cross-section B-B in FIG. 4, which reference cross-section is parallel to the lengthwise directions of protruding fins 28. Fin spacers 39 are also illustrated.

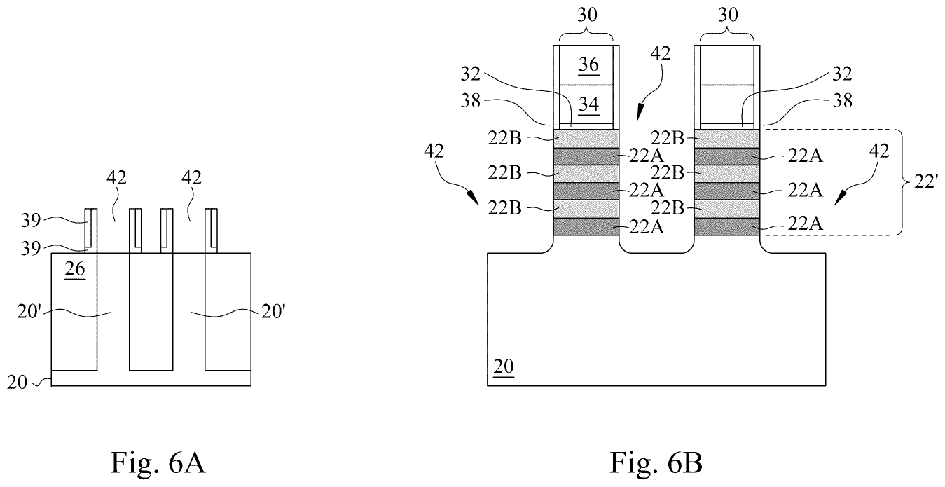

Referring to FIGS. 6A and 6B, the portions of protruding fins 28 that are not directly underlying dummy gate stacks 30 and gate spacers 38 are recessed through an etching process to form recesses 42. The respective process is illustrated as process 210 in the process flow 200 shown in FIG. 29. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight, as shown in FIG. 6B.

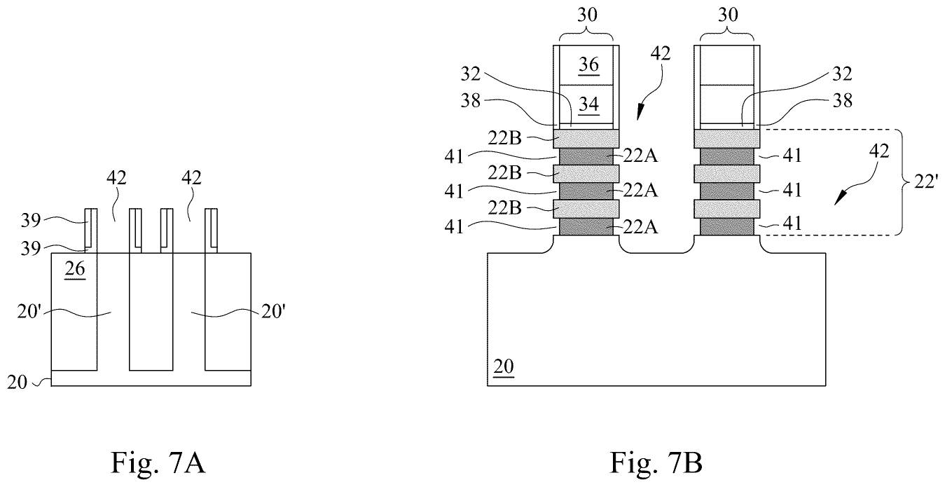

Referring to FIGS. 7A and 7B, sacrificial semiconductor layers 22A are laterally recessed to form lateral recesses 41, which are recessed from the edges of the respective overlying and underlying nanostructures 22B. The respective process is illustrated as process 212 in the process flow 200 shown in FIG. 29. The lateral recessing of sacrificial semiconductor layers 22A may be achieved through a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, or the like, and may be performed using any suitable process temperatures (for example, between about 400° C. and about 600° C.) and a suitable process time (for example, between about 100 seconds and about 1,000 seconds). In accordance with alternative embodiments, the lateral recessing of sacrificial semiconductor layers 22A is performed through an isotropic dry etching process or a combination of a dry etching process and a wet etching process.

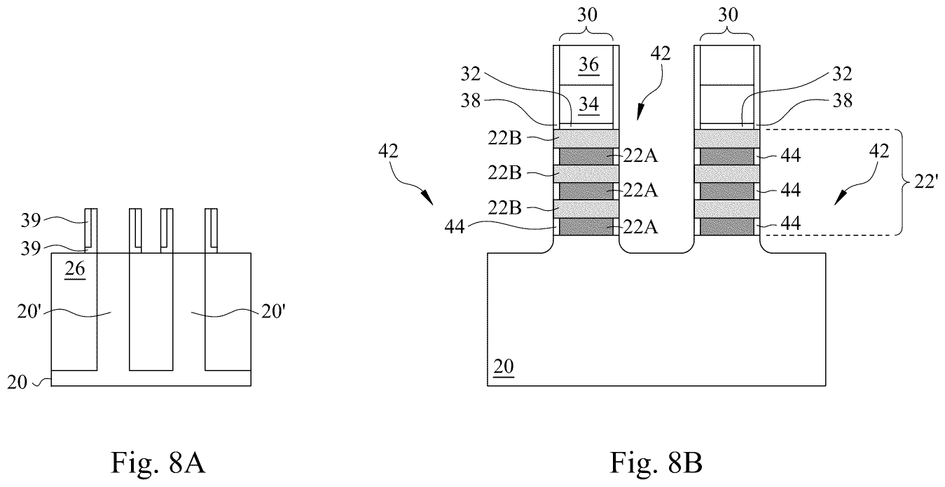

FIGS. 8A and 8B illustrate the formation of inner spacers 44. The respective process is illustrated as process 214 in the process flow 200 shown in FIG. 29. The formation process incudes depositing a spacer layer extending into recesses 41, and performing an etching process to remove the portions of inner spacer layer outside of recesses 41, thus leaving inner spacers 44 in recesses 41. Inner spacers 44 may be formed of or comprise SiOCN, SiON, SiOC, SiCN, or the like. Inner spacers 44 may also be porous so that they have a lower-k value lower than, for example, about 3.5. In accordance with some embodiments, the etching of the spacer layer may be performed through a wet etching process, in which the etching chemical may include H₂SO₄, diluted HF, ammonia solution (NH₄OH, ammonia in water), or the like, or combinations thereof.

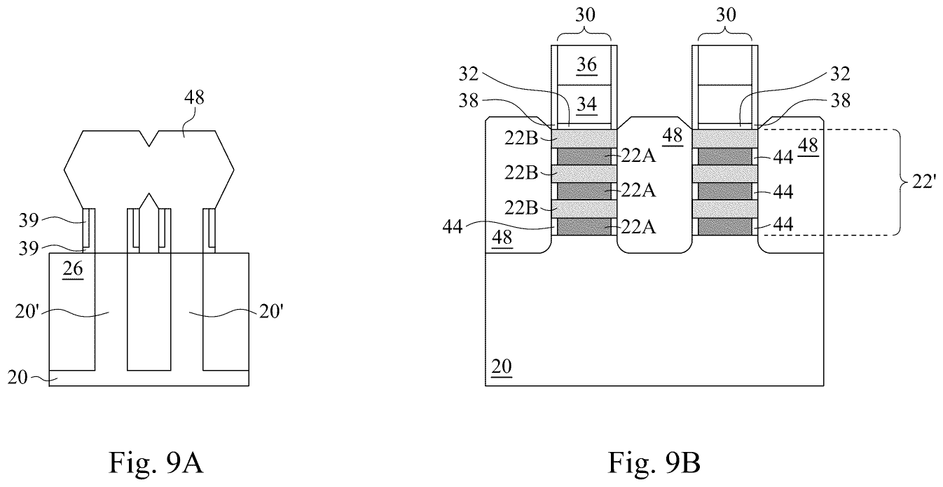

Referring to FIGS. 9A and 9B, epitaxial source/drain regions 48 are formed in recesses 42. The respective process is illustrated as process 216 in the process flow 200 shown in FIG. 29. In accordance with some embodiments, the source/drain regions 48 may exert stress on the nanostructures 22B, which are used as the channels of the corresponding GAA transistors, thereby improving performance. In accordance with some embodiments, the corresponding transistor is n-type, and epitaxial source/drain regions 48 are accordingly formed as of n-type by doping an n-type dopant. For example, silicon phosphorous (SiP), silicon carbon phosphorous (SiCP), or the like may be grown to form epitaxial source/drain regions 48. After recesses 42 are filled with epitaxy regions 48, the further epitaxial growth of epitaxy regions 48 causes epitaxy regions 48 to expand horizontally, and facets may be formed. The further growth of epitaxy regions 48 may also cause neighboring epitaxy regions 48 to merge with each other.

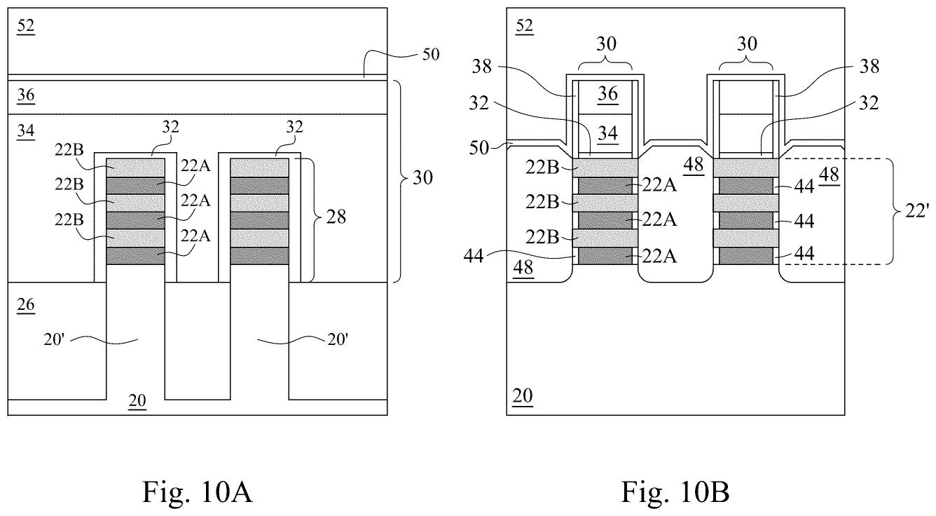

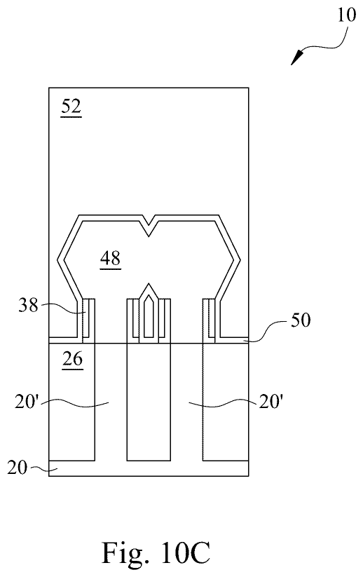

FIGS. 10A, 10B, and 10C illustrate the cross-sectional views of the structure after the formation of Contact Etch Stop Layer (CESL) 50 and Inter-Layer Dielectric (ILD) 52. FIGS. 10A, 10B, and 10C are obtained from the same cross-section same as the cross-sections A2-A2, B-B, and A1-A1, respectively, in FIG. 4. The respective process is illustrated as process 218 in the process flow 200 shown in FIG. 29. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be a silicon-oxide based material such as silicon oxide, Phospho-Silicate Glass (PSG), Boro-Silicate Glass (BSG), Boron-Doped Phospho-Silicate Glass (BPSG), Undoped Silicate Glass (USG), or the like.

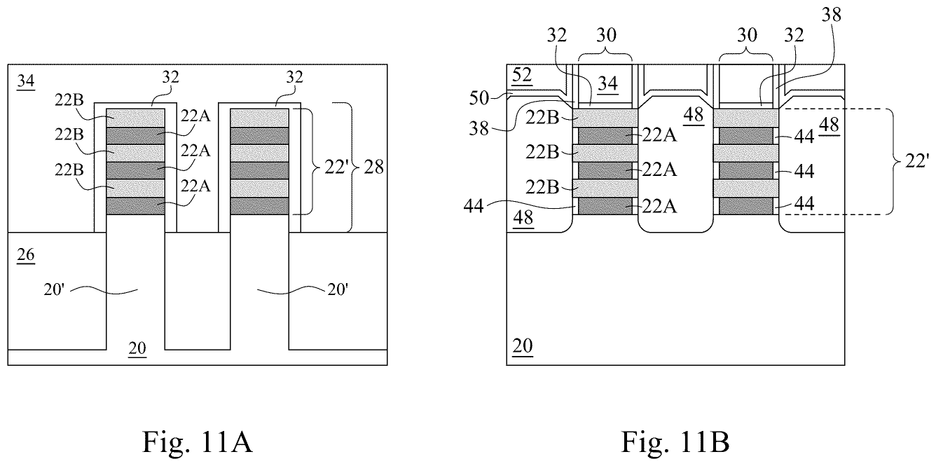

In subsequent processes, replacement gate stacks are formed to replace dummy gate stacks 30. Referring to FIGS. 11A and 11B, a planarization process such as a CMP process or a mechanical grinding process is performed to level the top surface of ILD 52. The respective process is illustrated as process 220 in the process flow 200 shown in FIG. 29. In accordance with some embodiments, the planarization process may remove hard masks 36 to reveal dummy gate electrodes 34, as shown in FIG. 11B. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level with each other within process variations.

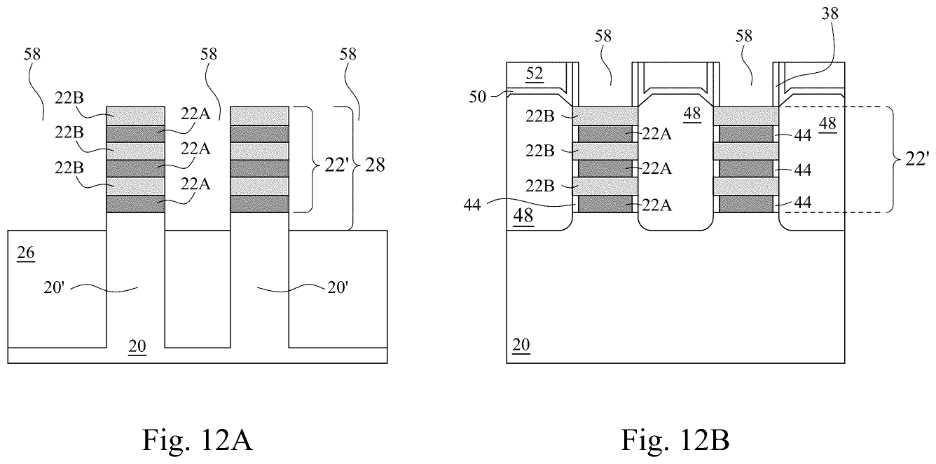

Next, dummy gate electrodes 34 (and hard masks 36, if remaining) are removed in one or more etching processes, so that recesses 58 are formed, as shown in FIGS. 12A and 12B. The respective process is illustrated as process 222 in the process flow 200 shown in FIG. 29. The portions of the dummy gate dielectrics 32 in recesses 58 are also removed. In accordance with some embodiments, dummy gate electrodes 34 and dummy gate dielectrics 32 are removed through dry etching processes. For example, the etching process may be performed using reaction gas(es) that selectively etch dummy gate electrodes 34 at a faster rate than ILD 52. Each recess 58 exposes and/or overlies portions of multilayer stacks 22′, which include the future channel regions in subsequently completed nano-FETs. The corresponding portions of the multilayer stacks 22′ are between neighboring pairs of the epitaxial source/drain regions 48.

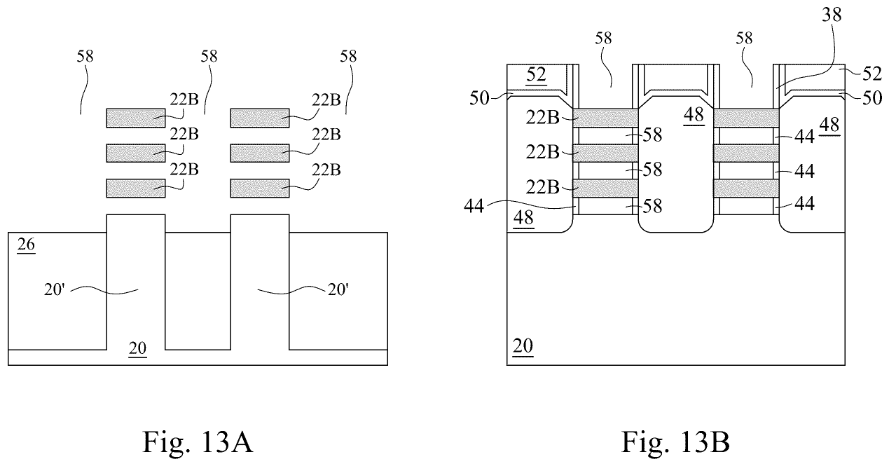

Sacrificial layers 22A are then removed to extend recesses 58 between nanostructures 22B, and the resulting structure is shown in FIGS. 13A and 13B. The respective process is illustrated as process 224 in the process flow 200 shown in FIG. 29. Sacrificial layers 22A may be removed by performing an isotropic etching process such as a wet etching process using etchants which are selective to the materials of sacrificial layers 22A. Nanostructures 22B, substrate 20, STI regions 26 remain relatively un-etched as compared to sacrificial layers 22A. In accordance with some embodiments in which sacrificial layers 22A include, for example, SiGe, and nanostructures 22B include, for example, Si or SiC, the etching chemical such as tetra methyl ammonium hydroxide (TMAH), ammonium hydroxide (NH₄OH), or the like may be used to remove sacrificial layers 22A.

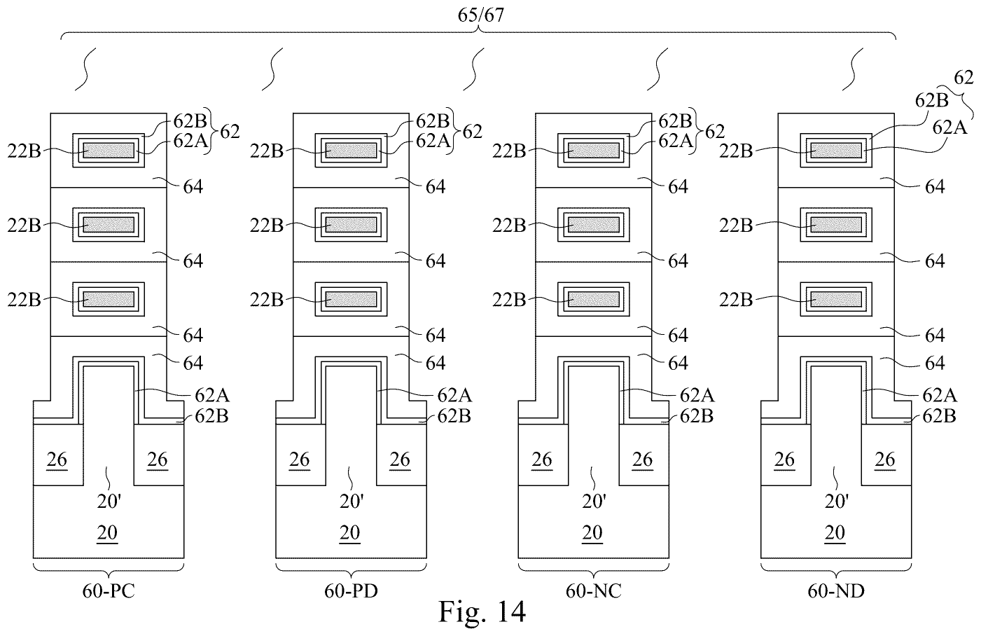

The preceding processes may be used for forming multiple GAA transistors with different Vts. In subsequent discussion, four device regions are illustrated, each for forming a transistor therein. For example, FIG. 14 illustrates device regions 60-PC, 60-PD, 60-NC, and 60-ND, and the structures shown therein are formed using the processes as discussed in preceding paragraphs. Device region 60-PD is a p-type transistor region, which is a region in which a p-type dipole drive-in process is to be performed. Device region 60-PC is a counterpart p-type transistor region, in which no p-type dipole drive-in process is to be performed. Device region 60-ND is an n-type transistor region, which is a region in which an n-type dipole drive-in process is to be performed. Device region 60-NC is a counterpart n-type transistor region, in which no n-type dipole drive-in process is to be performed.

Referring to FIG. 14, gate dielectrics 62 are formed to encircle semiconductor nanostructures 22B. The respective process is illustrated as process 226 in the process flow 200 shown in FIG. 29. In accordance with some embodiments, each of gate dielectrics 62 includes interfacial layer 62A and high-k dielectric layer 62B on the interfacial layer 62A. The interfacial layer 62A may be formed of or comprises silicon oxide, which may be deposited through a conformal deposition process such as ALD or CVD. In accordance with alternative embodiments, interfacial layer 62A is formed through thermal oxidation. When formed through thermal oxidation, the portions of interfacial layer 62A on the top surfaces of STI regions 26 will not be formed. In accordance with some embodiments, the high-k dielectric layers 62B comprise one or more dielectric layers. For example, the high-k dielectric layer(s) 62B may include a metal oxide or a silicate of hafnium, aluminum, zirconium, lanthanum, manganese, barium, titanium, lead, combinations thereof, and/or multi-layers thereof. High-k dielectric layer 62B is deposited through a conformal deposition process such as ALD or CVD.

FIGS. 14-17 illustrate the dipole doping of an n-type dipole dopant in device region 60-ND in accordance with some embodiments. Referring to FIG. 14, dipole film 64 is deposited on gate dielectric 62 through a conformal deposition process such as CVD, ALD, or the like. The respective process is illustrated as process 228 in the process flow 200 shown in FIG. 29. Dipole film 64 is deposited in device regions 60-PC, 60-PD, 60-NC, and 60-ND. Dipole film 64 may include an n-type dopant such as La, Sr, Y, Er, Sc, Mg, or the like, or combinations thereof. The n-type dopant, when incorporated into the gate dielectrics of n-type transistors, may reduce the effective work functions and hence reduce the threshold voltages of the corresponding n-type transistors.

The dipole film 64 may be deposited as the oxide and/or the nitride of the n-type dopant(s). In accordance with some embodiments, the dipole film 64 deposited on upper nanostructures 22B may be merged with the dipole film 64 deposited on the respective lower nanostructures 22B. In accordance with alternative embodiments, at the time the deposition is finished, dipole film 64 deposited on upper nanostructures 22B may be physically separated from the dipole film 64 deposited on the respective lower nanostructures 22B.

In accordance with some embodiments, dipole film 64 is trimmed back in trim back process 65. The trim back process 65 may be performed through an isotropic etching process to etch dipole film 64 isotropically, so that its thickness is reduced to a desirable value, such as in the range between about 17 Å and about 20 Å. In accordance with alternative embodiments, the trim back process 65 is skipped. The trim back process 65 may make the subsequent treatment process more effect due to the thinner dipole film 64, and the bonds of more dipole dopants close to high-k dielectric layer 62B may break, and the subsequent drive-in process is more effective.

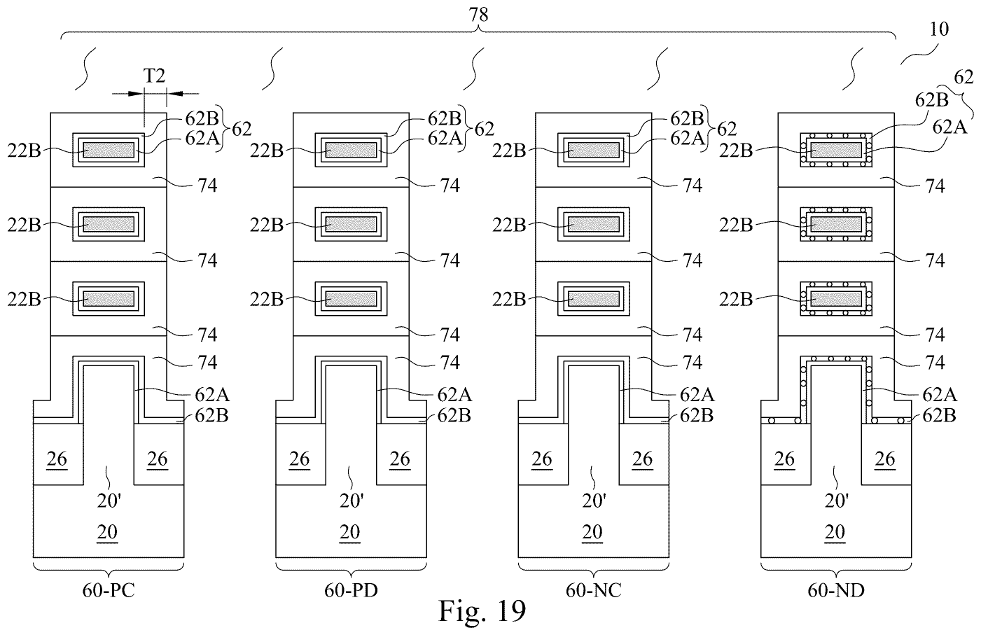

In accordance with some embodiments, after the trim back process 65, a treatment process 67 using N₂ and H₂ is performed to treat dipole film 64. The treatment process 67 may improve the efficiency of the drive-in process, and hence the atomic percentage (and the concentration) of the dipole dopant that is diffused into high-k dielectric layer 62B is increased than if the treatment is not performed. The details of the treatment process 67 including the process gases, the treatment method, the wafer temperature, and the like may be essentially the same as that of treatment process 78 (FIG. 19).

In accordance with alternative embodiments, in an entire period of time starting at a first time when dipole film 64 starts to be deposited and ending at a time the drive-in process 70 is finished, no treatment process using N₂ and H₂ is performed to treat dipole film 64. By not treating the dipole film 64, the dipole doping efficiency is lower, thus creating another Vt tuning level.

In accordance with alternative embodiments, the treatment process 67 is performed selectively on the dipole film 64 of some transistors, not but on the dipole film 64 of some other transistors. For example, in accordance with some embodiments, the dipole film 64 is to be left in both of device regions 60-NC and 60-ND. In the treatment process 67, the dipole film 64 in device region 60-ND is selectively treated. The dipole film 64 in device region 60-NC, on the other hand, is protected by a mask (not shown), and is not treated. As a result, the high-k dielectric layer 62B in device region 60-ND has a higher dipole dopant concentration (after the dopant drive-in) than the high-k dielectric layer 62B in device region 60-NC due to the higher drive-in efficiency. The threshold voltage of the transistor in device region 60-ND is thus lower than the threshold voltage of the transistor in device region 60-ND, thus two Vt tuning levels are created.

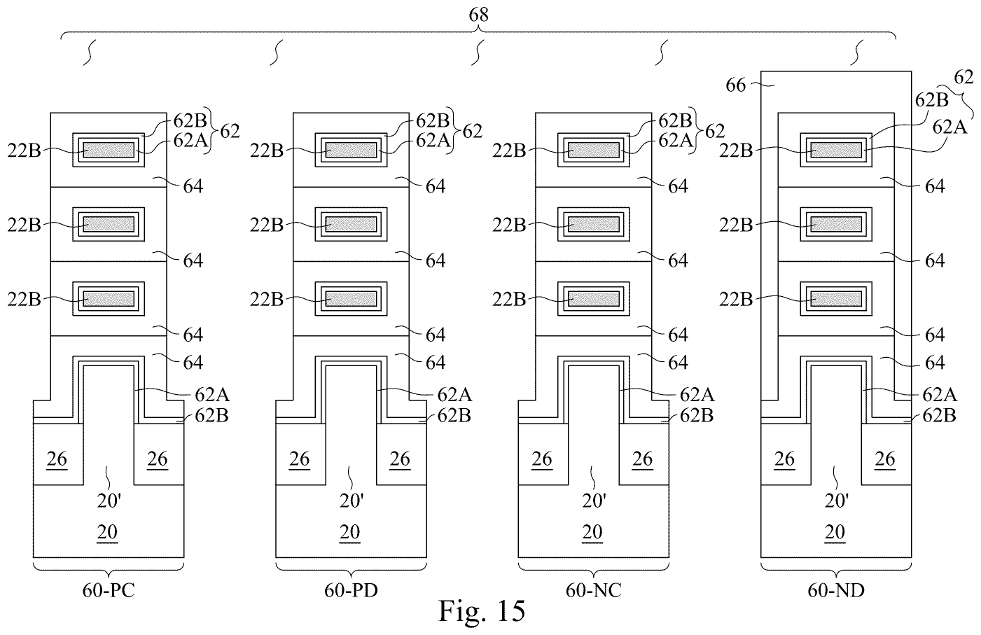

Referring to FIG. 15, after the trim back process 65 and the treatment process 67 (if any), a patterned etching mask 66 is formed. In accordance with some embodiments, the patterned etching mask 66 includes a bottom anti-reflective coating (BARC), which is patterned using a top layer that may comprise a patterned photoresist. The top layer is used to etch the BARC, so that the BARC has a portion left in device region 60-ND, and the portions of the BARC in device regions 60-PC, 60-PD, and 60-NC are removed. Etching mask 66 is then removed.

Further referring to FIG. 15, an etching/patterning process 68 is performed to etch dipole film 64. The respective process is illustrated as process 230 in the process flow 200 shown in FIG. 29. The etching process 68 may be performed before or after the treatment process 67 (if performed). In the etching process 68, etching mask 66 protects the portion of dipole film 64 in device region 60-ND, while the portions of dipole film 64 in device regions 60-PC, 60-PD, and 60-NC are removed. After the etching process 68, etching mask 66 is removed.

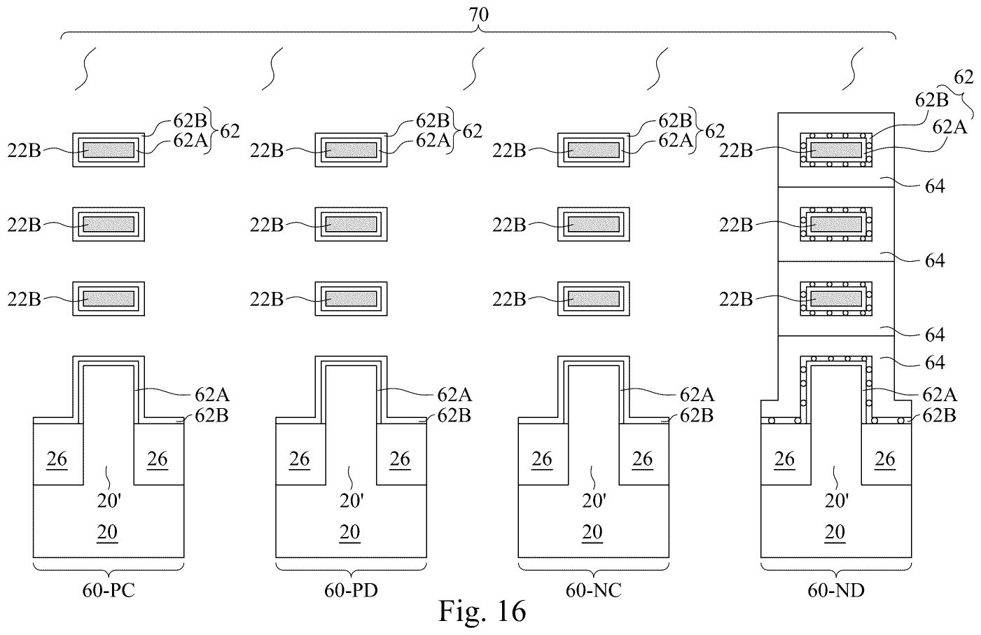

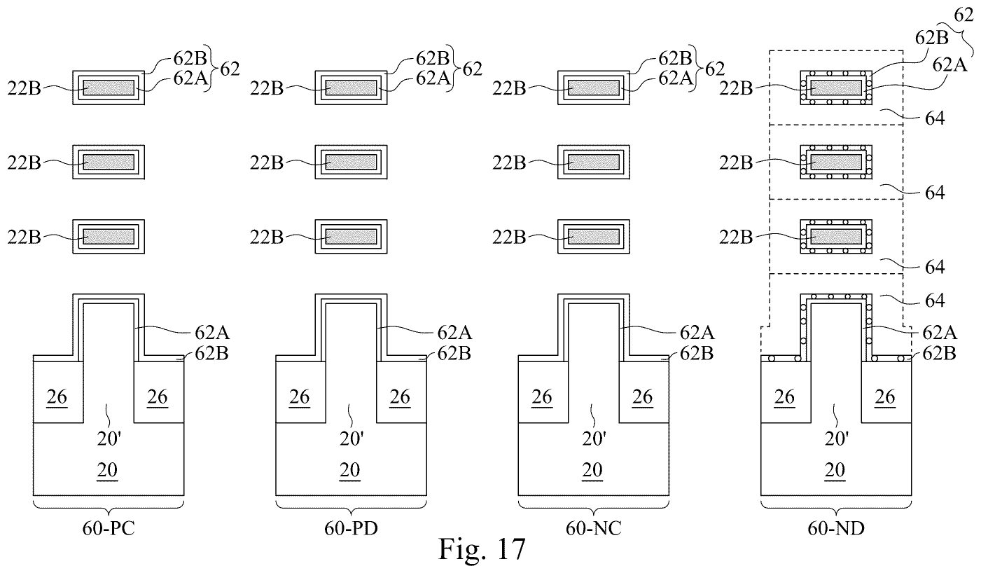

FIG. 16 illustrates drive-in process 70, which is performed through an annealing process, so that the dipole dopant in dipole film 64 is driven into high-k dielectric layer 62B. The respective process is illustrated as process 232 in the process flow 200 shown in FIG. 29. The drive-in process 70 may be performed in a process gas such as N₂, He, NH₃, Ar, or the like, or the mixtures thereof. In accordance with some embodiments, the drive-in process 70 is performed through a soak anneal process, a spike rapid thermal anneal process, or the like.

The drive-in process 70 drives the n-type dipole dopant (such as La) in dipole film 64 into the respective underlying high-k dielectric layers 62B in device region 60-ND. The circles represent the dipole dopants. The threshold voltage of the resulting transistor is thus tuned, for example, reduced.

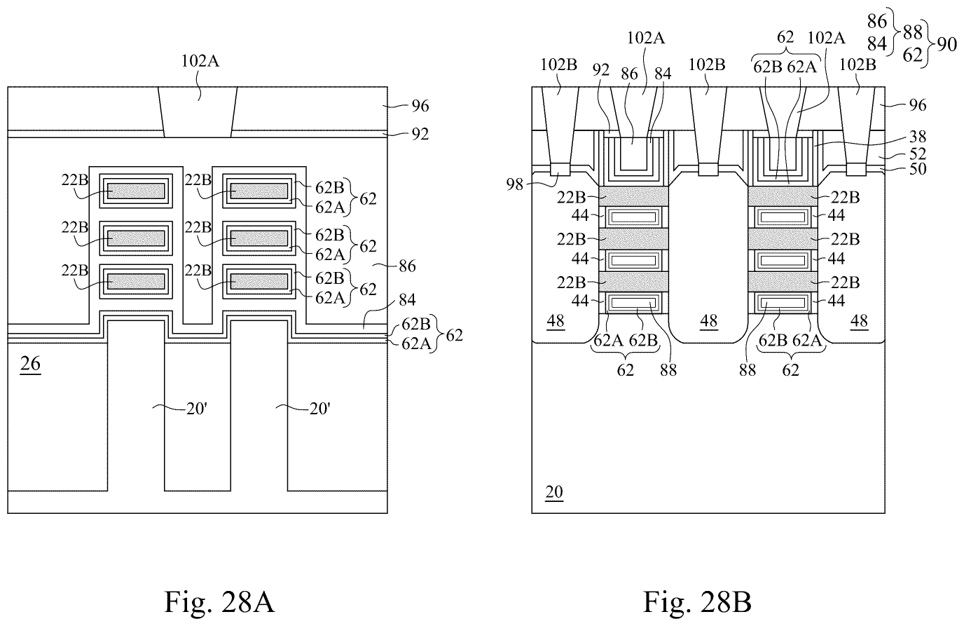

In accordance with some embodiments, the process conditions such as the annealing time and the temperature is controlled, so that the peak concentration of the dipole dopant (in the final transistors as shown in FIGS. 28A and 28B) is in high-k dielectric layer 62B, and may be closer to the interface between high-k dielectric layer 62B and interfacial layer 62A than the outer surface of high-k dielectric layer 62B. When the soak anneal process is adopted, the annealing duration may be in the range between about 5 seconds and about 5 minutes. The annealing temperature may be in the range between about 550° C. and about 900° C.

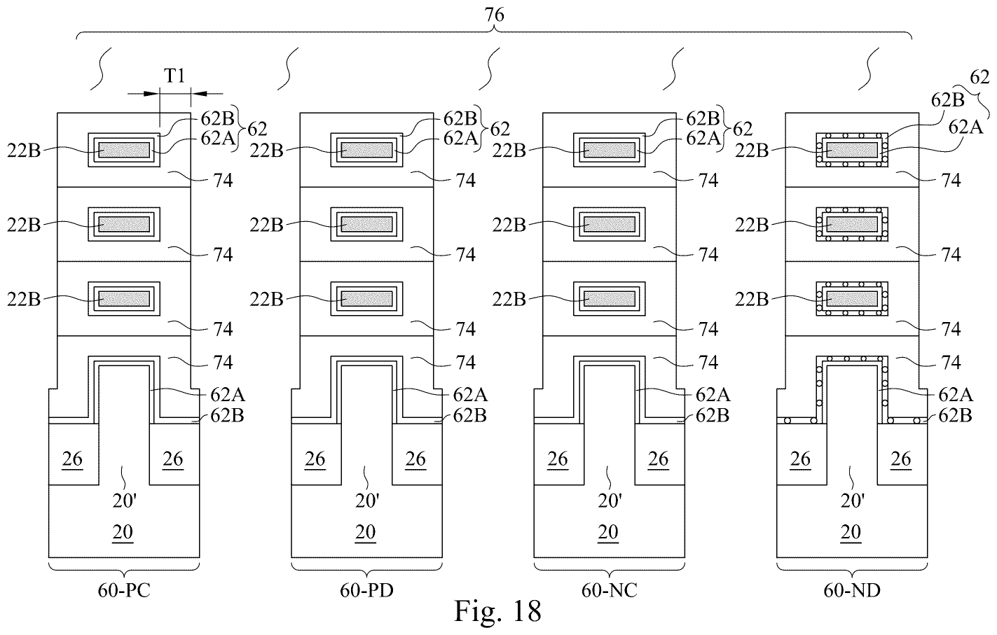

In accordance with some embodiments, after the drive-in process 70, the dipole film 64 as shown in FIG. 16 is removed in an etching process. The respective process is illustrated as process 234 in the process flow 200 shown in FIG. 29. In accordance with some embodiments, after the drive-in process 70, the dipole film 64 as shown in FIG. 16 is not removed, and hence the subsequently deposited dipole film 74 (FIG. 18) will be deposited on dipole film 64. In accordance with yet alternative embodiments, after the drive-in process 70, the dipole film 64 as shown in FIG. 16 is thinned, but not fully removed. The subsequently deposited dipole film 74 (FIG. 18) will also be deposited on the thinned dipole film 64. Accordingly, in FIG. 17, dipole film 64 is illustrated as being dashed to represent that it may be removed, thinned, or neither removed nor thinned.

FIGS. 18 through 24 illustrate the dipole doping of a p-type dipole dopant in device region 60-PD in accordance with some embodiments. Referring to FIG. 18, dipole film 74 is deposited on gate dielectric 62 through a conformal deposition process such as CVD, ALD, or the like. The respective process is illustrated as process 236 in the process flow 200 shown in FIG. 29. Dipole film 74 is deposited in device regions 60-PC, 60-PD, 60-NC, and 60-ND.

Dipole film 74 may include a p-type dopant, which when incorporated into the gate dielectrics of p-type transistors, may increase the effective work functions and hence reduce the threshold voltages of the corresponding p-type transistors. In accordance with some embodiments, the p-type dopant may include aluminum (Al), zinc (Zn), and/or the like. The dipole film 74 may be the oxide and/or the nitride of the dipole dopants. For example, dipole film 74 may comprises AlOₓ, AlOₓ, AlNₓ, TiAlₓN_{y}, or the like, or combinations thereof.

In accordance with some embodiments, the deposition of dipole film 74 may be performed using a conformal deposition process such as CVD, ALD, or the like. In accordance with some embodiments in which dipole film 64 includes portions remaining in device region 60-ND, the dipole film 74 is formed on and contacting the remaining dipole film 64. Otherwise, in device region 60-ND, dipole film 74 is over and contacting high-k dielectric layer 62B.

In accordance with some embodiments, the dipole film 74 deposited on upper nanostructures 22B may be merged with the dipole film 74 deposited on the respective lower nanostructures 22B. In accordance with alternative embodiments, the dipole film 74 deposited on upper nanostructures 22B may be physically separated from the dipole film 74 deposited on the respective lower nanostructures 22B at the time the deposition is finished.

In accordance with some embodiments, as also shown in FIG. 18, dipole film 74 is trimmed back in a trim back process 76, for example, through an isotropic etching process. The resulting structure is shown in FIG. 19. The respective process is illustrated as process 238 in the process flow 200 shown in FIG. 29. Through the trim back process, the thickness of dipole film 74 may be reduced from thickness T1 (FIG. 18) to thickness T2 (FIG. 19). The thickness T2 of dipole film 74 may be in the range between about 17 Å and about 20 Å. In accordance with alternative embodiments, the trim back process 76 is skipped.

In accordance with some embodiments, as shown in FIG. 19, treatment process 78 is performed. The respective process is illustrated as process 240 in the process flow 200 shown in FIG. 29. The treatment may be performed using the mixture of N₂ and H₂ as a process gas. In accordance with some embodiments, the treatment process 78 may be performed in a process chamber, which may be used for ashing processes in accordance with some embodiments. In accordance with some embodiments, the treatment process 78 is performed with N₂ having a flow rate in the range between about 1,000 sccm and about 4,000 sccm, and H2 having a flow rate in the range between about 1,500 sccm and about 4,500 sccm.

The treatment process 78 may also be a plasma treatment process, with wafer 10 being exposed to the plasma generated from the treatment gas. In accordance with some embodiments, the treatment process 78 may be performed with the wafer 10 not heated in order to minimize the thermal budget and the drifting of the threshold voltage due to the thermal budget. In accordance with alternative embodiments, the treatment process may be a thermal treatment process, in which the respective wafer 10 is heated to a temperature in a range between about 245° C. and about 260° C. The thermal treatment duration may be in the range between about 0.3 minutes and about 15 minutes. The treatment process may also be both of a thermal treatment process and a plasma treatment process. The plasma treatment duration may be in the range between about 0.3 minutes and about 1.5 minutes.

In accordance with some embodiments, the process conditions (such as the source power for generating the plasma, the partial pressure and/or the flow rate of N₂ and H₂) of treatment process 78 are the same as that of the treatment process 67 (FIG. 14) for treating dipole film 64. In accordance with alternative embodiments, the process conditions of treatment process 78 is different from the treatment process 67 for treating dipole film 64.

In accordance with some embodiments, the treatment process 78 may result in radicals and/or ions of hydrogen and nitrogen to be generated, and incorporated into high-k dielectric layer 62B. The treatment process 78 may also break the bonds of dipole film 64, which bonds are formed between the dipole dopant atoms and oxygen and/or nitrogen atoms. It is thus easier to drive the dipole dopant into the high-k dielectric layer 62B. The concentration and atomic percentage of the dipole dopant in the high-k dielectric layer 62B thus may be higher than if treatment process 78 is not performed. The threshold voltage tuning (the reduction in the threshold voltage) due to the dipole dopant incorporation is hence more significant.

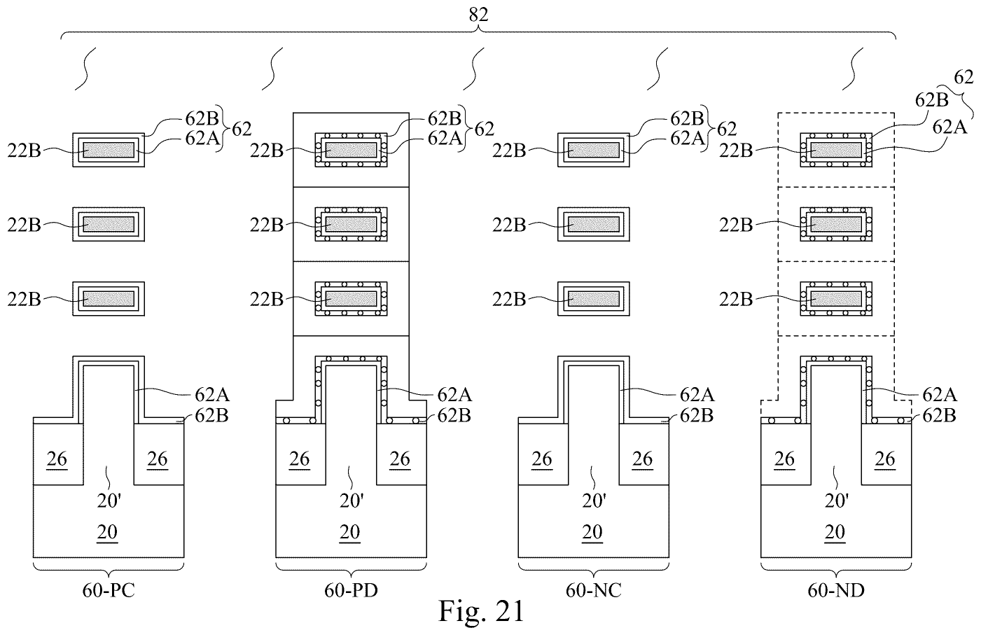

The treatment process 78 may be performed on all dipole film 74 in all device regions, or may be performed selectively on some, but not all of device regions. For example, the treatment process 78 may be performed on the dipole film 74 in device region 60-PD, but not on the dipole film 74 in device region 60-PC. In accordance with these embodiments, when the selective treatment process is performed, the dipole film 74 in both of device regions 60-PC and 60-PD are not removed, and the drive-in process 82 (FIG. 21) will drive the dipole dopant in both of device regions 60-PC and 60-PD into the respective high-k dielectric layers 62B. Due to the selective treatment process, the high-k dielectric layer 62B in device region 60-PD (which receives the selective treatment) will have higher dipole dopant percentage (and dipole dopant concentration) than that in device region 60-PC (which does not receive the selective treatment process 78). Accordingly, the threshold voltage of the transistor in device region 60-PD will be lower than that of the threshold voltage of the transistor in device region 60-PC.

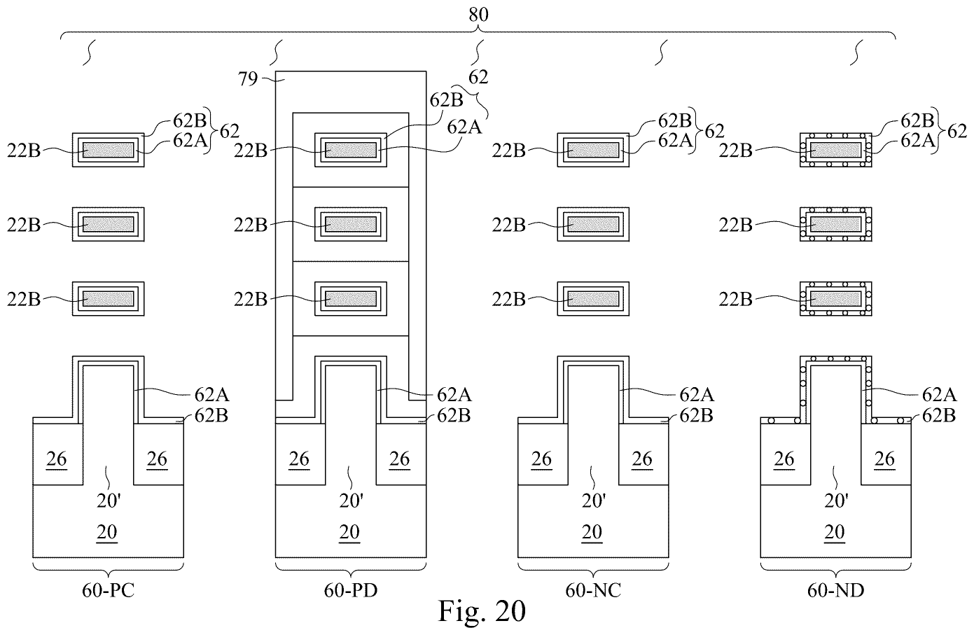

Referring to FIG. 20, a patterned etching mask 79 is formed. In accordance with some embodiments, the patterned etching mask 79 includes a BARC, which is patterned using a top layer that may comprises a patterned photoresist. The top layer is used to etch the BARC, so that the BARC has a portion left in device region 60-PD, and the portions of etching mask 79 in device regions 60-PC, 60-NC, and 60-ND are removed.

Further referring to FIG. 20, an etching/patterning process(es) 80 is performed to etch some portions of dipole film 74. The respective process is illustrated as process 242 in the process flow 200 shown in FIG. 29. In the etching process, etching mask 79 protects the dipole film 74 in device region 60-PD, while the dipole film 74 in device regions 60-PC, 60-NC, and 60-ND are removed. After the etching process 80, etching mask 79 is removed. In accordance with some embodiments in which dipole film 64 is left in device region 60-ND (as shown in FIG. 17), the dipole film 64 in device region 60-ND remains unremoved.

In accordance with some embodiments, the treatment process 78 is performed before dipole film 74 is patterned. In accordance with alternative embodiments, the treatment process 78 is performed after dipole film 74 is patterned.

FIG. 21 illustrates drive-in process 82 through an annealing process. The respective process is illustrated as process 244 in the process flow 200 shown in FIG. 29. The drive-in process 82 may be performed in a process gas such as N₂, He, NH₃, Ar, or the like, or the mixture thereof. In accordance with some embodiments, the drive-in process 82 is performed through a soak anneal process, a spike rapid thermal anneal process, or the like. In accordance with some embodiments, the process conditions such as the annealing time and the temperature is controlled, so that the peak concentration of the dipole dopant is in high-k dielectric layer 62B, and may be close to the interface between high-k dielectric layer 62B and interfacial layer 62A. When the soak anneal process is adopted, the annealing duration may be in the range between about 5 seconds and about 5 minutes. The annealing temperature may be in the range between about 550° C. and about 900° C.

In accordance with some embodiments, the process conditions (such as the duration, method, and/or the temperature) of drive-in process 82 are different from the process conditions of drive-in process 70 (FIG. 16) to suit to the different diffusion rate of different dipole dopants.

The drive-in process 82 drives the p-type dipole dopant (such as Al) in dipole film 74 into the respective underlying high-k dielectric layers 62B in device region 60-PD. The circles represent the dipole dopants. The threshold voltage of the resulting transistor is thus tuned, for example, reduced.

In accordance with some embodiments in which dipole film 64 has some portions left in device region 60-ND (refer to the dashed dipole film 64 in FIG. 17) when drive-in process 82 is performed, more n-type dipole dopant in device region 60-ND is also driven into the respective portion of high-k dielectric layers 62B in device region 60-ND by drive-in process 82. The concentration of n-type dipole dopant in high-k dielectric layers 62B in device region 60-ND is thus further increased, and the threshold voltage of the transistor in device region 60-ND is further reduced, creating another level of Vt tuning.

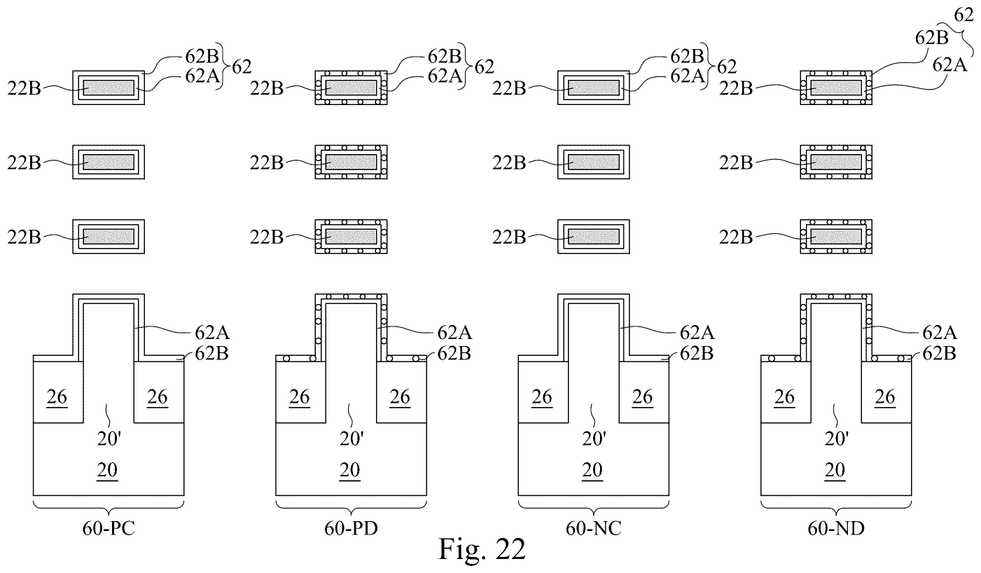

In accordance with some embodiments, after the drive-in process 82, the dipole film 74 as shown in FIG. 21 is removed in an etching process. The respective process is illustrated as process 246 in the process flow 200 shown in FIG. 29. Dipole film 64, if any is left, is also removed. The resulting structure is shown in FIG. 22.

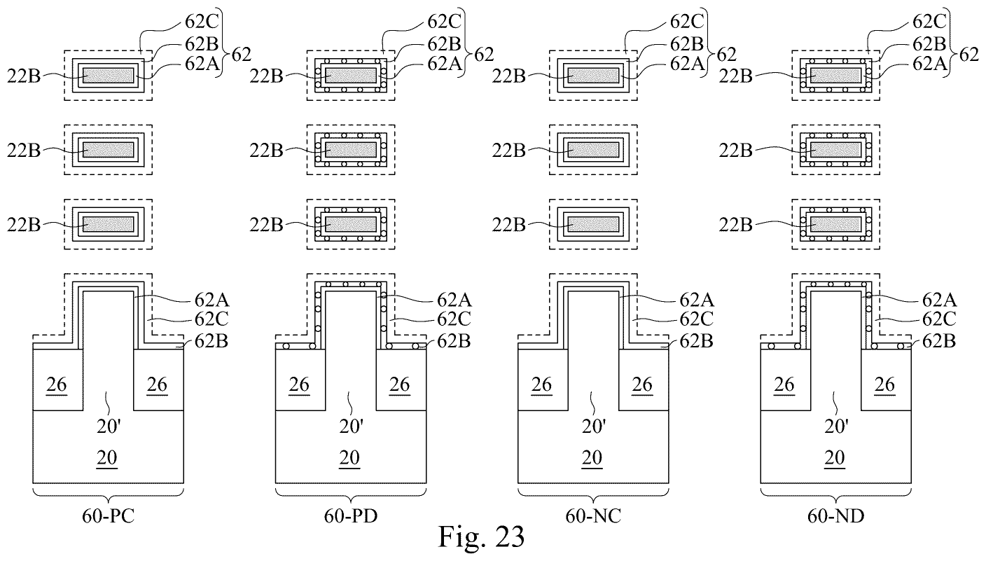

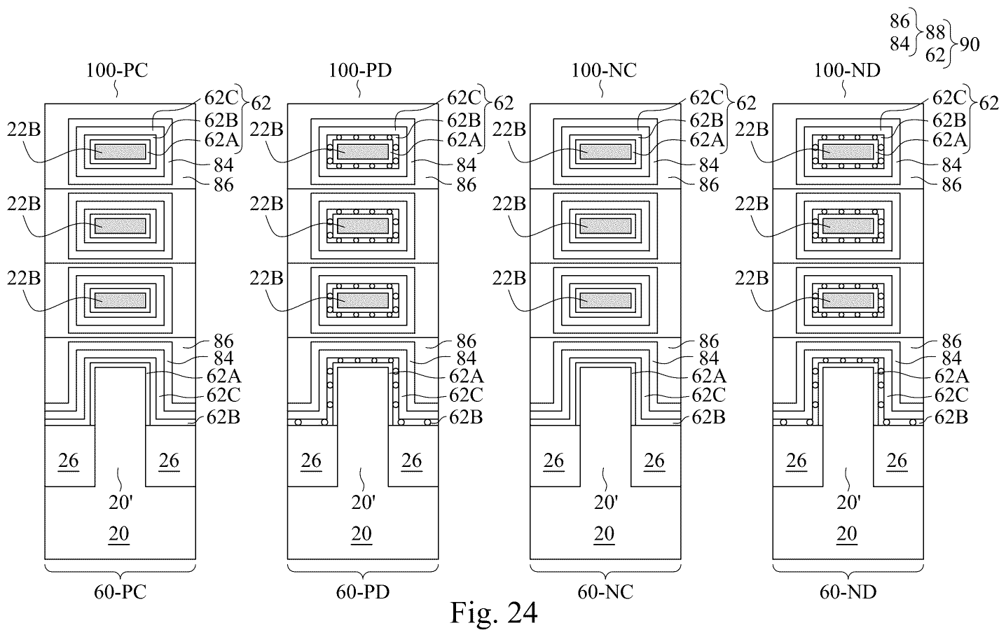

FIGS. 23 and 24 illustrate the formation of the remaining portions of gate stacks and the corresponding transistors in accordance with some embodiments. The respective process is illustrated as process 248 in the process flow 200 shown in FIG. 29. Referring to FIG. 23, a second high-k dielectric layer 62C is deposited to further form gate dielectrics 62. The material of the second high-k dielectric layer 62C may be the same as or different from the material of the high-k dielectric layer 62B. In accordance with alternative embodiments, no more high-k dielectric layer is deposited on high-k dielectric layer 62B, and the subsequently deposited conductive layers (including adhesion, barrier, and/or capping layer(s)) is in contact with high-k dielectric layer 62B. Accordingly, high-k dielectric layer 62C is illustrated as being dashed to indicate that it may or may not be formed.

Next, as shown in FIG. 24, conductive layers 84 and filling metal 86 are formed. In accordance with some embodiments, conductive layers 84 and filling metal 86 in device regions 60-PC and 60-PD are formed in common processes and using common materials, or formed in different processes using different materials. The conductive layers 84 and filling metal 86 in device regions 60-NC and 60-ND may be formed in common processes and using common materials, or in different processes using different materials. For example, the transistors formed in device regions 60-PC and 60-PD are of opposite conductivity types than the transistors formed in device regions 60-NC and 60-ND. Accordingly, the work-function layers in device regions 60-PC and 60-PD may be formed of different materials than that of the transistors in 60-NC, and 60-ND.

In accordance with some embodiments, the conductive layers 84 in device regions 60-PC and 60-PD may include a p-type work-function layer, which may include TiN, TaN, TiSiN, WCN, MOCN, or the combinations thereof. The conductive layers 84 in device regions 60-NC and 60-ND may include an n-type work-function layer, which may include TiAlC, TiAlN, TaAlC, TaAlN, or the like, or combinations thereof.

Filling metal 86 may be formed to fill the remaining recesses 58 (FIGS. 13A and 13B) if they are not fully filled yet. Filling metal 86 may include a metal-containing material such as cobalt, ruthenium, aluminum, tungsten, combinations thereof, and/or multilayers thereof. Transistors 100-PC, 100-PD, 100-NC, and 100-ND are thus formed in device regions 60-PC, 60-PD, 60-NC, and 60-ND, respective, as shown in FIG. 24.

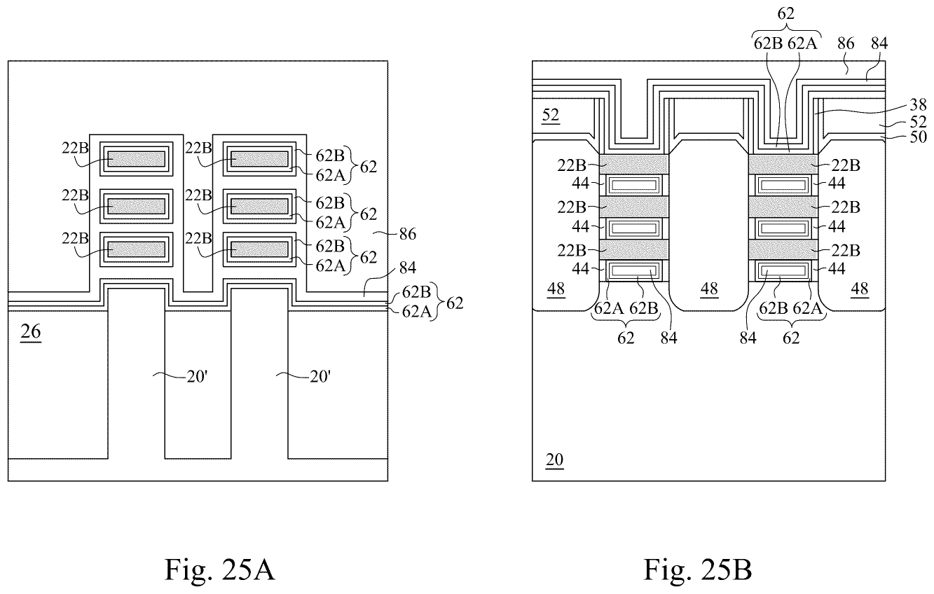

FIGS. 25A and 25B through 28A and 28B illustrate the formation of remaining gate stacks and contact plugs in accordance with some embodiments. The subsequent figure numbers in FIGS. 25A and 25B through 28A and 28B may have the corresponding numbers followed by letter A or B. The letter A indicates that the corresponding figure shows a cross-section same as the cross-section A2-A2 in FIG. 4, and the letter B indicates that the corresponding figure shows a reference cross-section same as the reference cross-section B-B in FIG. 4. Each of the structures in device regions 60-PC, 60-PD, 60-NC, and 60-ND (FIG. 22) may be formed by the processes in FIGS. 25A and 25B through 28A and 28B to finish the formation of transistors, with the transistors having tuned or un-tuned threshold voltage. Accordingly, the formation process as shown in FIGS. 25A and 25B through 28A and 28B may represent the formation of each of the transistors in FIG. 24.

Referring to FIGS. 25A and 25B, stacked conductive layers 84 and filling metal 86 are formed. The processes have been discussed referring to FIGS. 23 and 24. In FIGS. 25A and 25B, high-k dielectric layer 62C is not shown, while it may also exist.

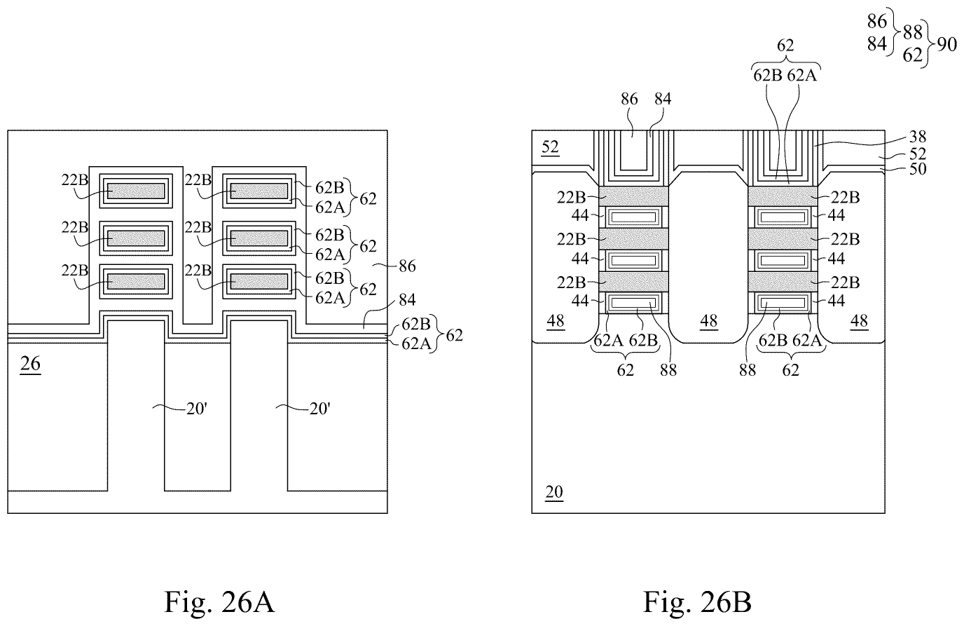

Referring to FIGS. 26A and 26B, after the filling of recesses 58, a planarization process such as a CMP process or a mechanical grinding process is performed to remove the excess portions of the gate dielectrics and the material of the stacked conductive layers 84 and filling metal 86, which excess portions are over the top surface of ILD 52. The remaining portions of the conductive layers 84 and filling metal 86 form gate electrodes 88. Gate electrodes 88 and gate dielectrics 62 are collectively referred to as gate stacks 90.

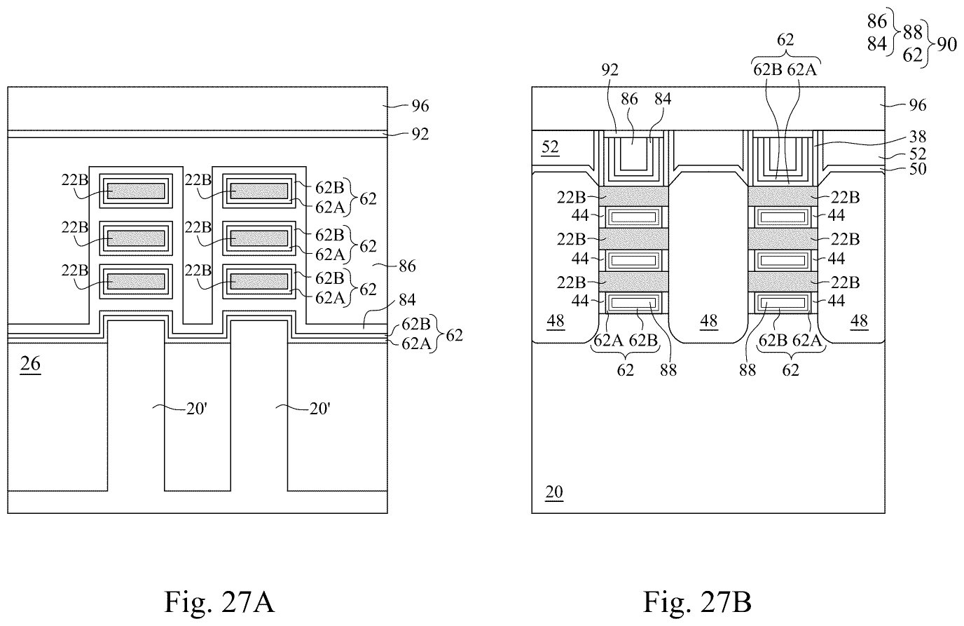

Next, as shown in FIGS. 27A and 27B, gate stacks 90 are recessed, so that recesses are formed directly over gate stacks 90 and between opposing portions of gate spacers 38. Gate mask 92 comprising one or more layers of dielectric material, such as silicon nitride, silicon oxynitride, or the like, are filled in the recesses, followed by a planarization process to remove excess portions of the dielectric material extending over ILD 52.

As further illustrated by FIGS. 27A and 27B, ILD 96 is deposited over ILD 52 and over gate masks 92. An etch stop layer (not shown) may be, or may not be, deposited before the formation of ILD 96. In accordance with some embodiments, ILD 96 is formed through FCVD, CVD, PECVD, or the like. ILD 96 is formed of a dielectric material, which may be selected from silicon oxide, PSG, BSG, BPSG, USG, or the like.

In FIGS. 28A and 28B, ILD 96, ILD 52, CESL 50, and gate masks 92 are etched to form recesses (occupied by contact plugs 102A and 102B), through which the surfaces of the epitaxial source/drain regions 48 and/or gate stacks 90 are exposed. The recesses may be formed through etching using an anisotropic etching process, such as reactive ion etching (RIE), neutral beam etching (NBE), or the like.

After the recesses are formed, silicide regions 98 (FIG. 28B) are formed over the epitaxial source/drain regions 48. Source/drain contact plugs 102B are then formed over silicide regions 98. Also, gate contacts 102A are formed in the recesses, and are over and contacting gate electrodes 88. Although FIG. 28B illustrates that contact plugs 102A and 102B are in a same cross-section, in various embodiments, contact plugs 102A and 102B may be formed in different cross-sections, thereby reducing the risk of shorting with each other. GAA transistors 100-PC, 100-PD, 100-NC, and 100-ND, which are represented by GAA transistor 100, are thus formed in device regions 60-PC, 60-PD, 60-NC, and 60-ND (FIG. 24), respectively.

By performing the treatment process on the dipole film, more dipole dopant may be doped into the high-k dielectric layer. For example, when aluminum is used as the p-type dipole dopant, and when using Energy Dispersive Spectroscopy (EDS) to detect the signal of aluminum in a high-k dielectric layer, the signal strength is 1.7 (normalized value) if no treatment is performed. When a treatment process is performed on the respective dipole film for about 20 seconds to about 30 seconds, the signal strength may increase to about 1.9, indicating that the aluminum concentration in the high-k dielectric layer is increased.

The embodiments of the present disclosure have some advantageous features. By performing the treatment process, more dipole dopant may be doped into high-k dielectric layers of transistors, and the ability of tuning threshold voltage is improved.

In accordance with some embodiments of the present disclosure, a method comprises forming a first source/drain region based on a first portion of a first semiconductor region; forming a first high-k dielectric layer based on a second portion of the first semiconductor region; forming a first dipole film on the first high-k dielectric layer; performing a first treatment process on the first dipole film using a process gas comprising nitrogen and hydrogen; performing a first drive-in process to drive a first dipole dopant in the first dipole film into the first high-k dielectric layer; and depositing a first work-function layer on the first high-k dielectric layer.

In an embodiment, the method further comprises removing the first dipole film after the first drive-in process. In an embodiment, the method further comprises, after the first dipole film is removed, depositing a second high-k dielectric layer over the first high-k dielectric layer. In an embodiment, the method further comprises, before the first drive-in process, trimming back the first dipole film. In an embodiment, the first treatment process comprises a plasma treatment process. In an embodiment, the first treatment process is performed without heating a wafer that comprises the first dipole film.

In an embodiment, the first source/drain region is a p-type source/drain region, and the method further comprises forming a second source/drain region based on a first portion of a second semiconductor region, wherein the second source/drain region is of n-type; forming a second high-k dielectric layer based on a second portion of the second semiconductor region; forming a second dipole film on the second high-k dielectric layer, wherein the second dipole film comprises a second dipole dopant different from the first dipole dopant; performing a second drive-in process to drive the second dipole dopant into the second high-k dielectric layer; and depositing a second work-function layer on the second high-k dielectric layer.

In an embodiment, the method further comprises performing a second treatment process on the second dipole film using an additional process gas comprising nitrogen and hydrogen, wherein the first treatment process and the second treatment process are separate processes. In an embodiment, the first treatment process and the second treatment process are performed using different process conditions. In an embodiment, the first dipole dopant comprises lanthanum.

In an embodiment, the first semiconductor region comprises a semiconductor nanostructure. In an embodiment, the method further comprises forming an additional high-k dielectric layer on an additional semiconductor region, wherein the first dipole film further comprises an additional portion formed on the additional high-k dielectric layer; and before the first drive-in process, removing the additional portion of the first dipole film.

In accordance with some embodiments of the present disclosure, a method comprises forming an interfacial layer on a first semiconductor region and a second semiconductor region; forming a first high-k dielectric layer on the interfacial layer and on the first semiconductor region and the second semiconductor region; depositing a dipole film on the first high-k dielectric layer, wherein the dipole film comprises a first portion overlapping the first semiconductor region and a second portion overlapping the second semiconductor region; performing a plasma treatment process on the dipole film; removing the second portion of the dipole film; performing a drive-in process to drive a dipole dopant in the dipole film into the first high-k dielectric layer; and forming a first gate electrode and a second gate electrode on the first high-k dielectric layer, wherein the first gate electrode and the second gate electrode are on the first semiconductor region and the second semiconductor region, respectively.

In an embodiment, the plasma treatment process is performed using a process gas comprising nitrogen and hydrogen. In an embodiment, the first semiconductor region and the second semiconductor region are semiconductor nanostructures, and wherein the first portion and the second portion of the dipole film encircle the first semiconductor region and the second semiconductor region, respectively. In an embodiment, the method further comprises removing the dipole film after the drive-in process; and depositing a second high-k dielectric layer on the first high-k dielectric layer.

In accordance with some embodiments of the present disclosure, a method comprises depositing a high-k dielectric layer encircling a semiconductor nanostructure; depositing a dipole film encircling the high-k dielectric layer; trimming the dipole film; performing a treatment process on the dipole film using nitrogen (N₂) and hydrogen (H₂); performing an anneal process on the dipole film that has been treated; removing the dipole film; depositing a second high-k dielectric layer on the high-k dielectric layer; and forming a gate electrode on the second high-k dielectric layer. In an embodiment, the treatment process is performed through plasma treatment process. In an embodiment, the depositing the dipole film comprises depositing aluminum oxide. In an embodiment, the depositing the dipole film comprises depositing lanthanum oxide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first source/drain region based on a first portion of a first semiconductor region;
forming a first high-k dielectric layer based on a second portion of the first semiconductor region;
forming a first dipole film on the first high-k dielectric layer;
performing a first treatment process on the first dipole film using a process gas comprising nitrogen and hydrogen;
performing a first drive-in process to drive a first dipole dopant in the first dipole film into the first high-k dielectric layer; and
depositing a first work-function layer on the first high-k dielectric layer;
removing the first dipole film after the first drive-in process after the first dipole film is removed; and
after the first dipole film is removed, depositing a second high-k dielectric layer over the first high-k dielectric layer.
